(19) United States
(12) Patent Application Publication
(10) Pub. No.: US 2025/0290193 A1
(43) Pub. Date: Sep. 18, 2025

(54) MOLYBDENUM PHYSICAL VAPOR DEPOSITION TARGET

(71) Applicant: Applied Materials, Inc., Santa Clara, CA (US)

(72) Inventors: Goichi YOSHIDOME, Albany, CA (US); William R. JOHANSON, JR., Gilroy, CA (US); Sang-Heum KIM, Mountain View, CA (US); Wenting HOU, Sunnyvale, CA (US)

(21) Appl. No.: 19/077,807

(22) Filed: Mar. 12, 2025

Related U.S. Application Data
(60) Provisional application No. 63/564,797, filed on Mar. 13, 2024.

(51) Int. Cl. C23C 14/34; C23C 14/14

(52) U.S. Cl. CPC C23C 14/3414; C23C 14/14

(57) ABSTRACT

A physical vapor deposition (PVD) chamber deposits thin films on substrates by forming a high density plasma with a PVD target. More particularly, apparatus and methods are presented that improve film deposition uniformity when a target material of the PVD target includes a molybdenum PVD target material and a density of 99% or greater.

### CROSS-REFERENCE TO RELATED APPLICATIONS

This application is a conversion of U.S. provisional Patent Application Ser. No. 63/564,797, filed Mar. 13, 2024, which is incorporated herein by reference.

### BACKGROUND

### Field

Embodiments of the present subject matter generally relates to physical vapor deposition. More particularly, the subject matter relates to a sputtering target for use in a physical vapor deposition chamber and process.

### Description of the Related Art

Physical Vapor Deposition (PVD) is a crucial thin-film deposition technique extensively employed in semiconductor substrate processing to create thin layers of materials with enhanced properties. PVD operates under vacuum conditions and involves the evaporation or sputtering of target materials, such as metals or ceramics, onto a semiconductor substrate to form thin films. In sputtering, high-energy ions bombard the target material of the target assembly, dislodging atoms from a target that are then deposited onto the substrate. PVD is highly versatile, allowing for precise control over film thickness, uniformity, and composition, making it ideal for fabricating various semiconductor components, including integrated circuits, microelectromechanical systems (MEMS), and optical coatings. The deposited thin films provide essential functionalities, such as conductive layers for interconnections and diffusion barriers, and contribute to enhancing device performance, reliability, and miniaturization in modern semiconductor manufacturing processes.

The choice of target material is important as it directly determines the properties and characteristics of the thin film being deposited. Different applications require different materials with specific properties. For example, semiconductor devices may require thin films made of metals like aluminum, molybdenum, copper, or tungsten for interconnects and thermal management, or dielectric materials like silicon dioxide or silicon nitride for insulating layers. Other specialized applications may demand exotic materials like magnetic alloys or refractory compounds. In all target material choices, throughput and target life are always a key consideration when reviewing a manufacturing process.

To ensure high-quality thin films, the target material must be pure and have a uniform composition. Additionally, the design of a target assembly, target life span, the shape and size of the target material, and the corresponding relations all influence the deposition process, as they influence the distribution, thickness of the deposited thin film on the substrate, and service life of the target assembly.

Therefore, there exists a need in the art for a sputtering target apparatus with an improved life span.

### SUMMARY

The disclosure relates to a target for physical vapor deposition processes. In one embodiment, a physical vapor deposition (PVD) target, includes a target material of the PVD target includes a molybdenum PVD target material and a density of 99% or greater.

In another embodiment, a PVD target, includes a backer plate and a molybdenum target material disposed on the backer plate. The molybdenum target includes a density of 99% or greater.

In another embodiment, a method of sputtering includes disposing a substrate within a chamber, supplying DC power to a physical vapor deposition (PVD) target, and depositing a molybdenum layer on the substrate. The target includes a backer plate and a target material disposed on the backer plate, the target material has a density of 99% or greater

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 is a schematic view of a physical vapor deposition processing system.

FIG. 2 is schematic, cross-sectional view of a target assembly according to some embodiments described herein.

FIG. 3 is partial schematic, cross-sectional view of a target assembly according to some embodiments described herein.

FIG. 4 is a flow diagram of a method of sputtering according to one or more embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of target assemblies for use in substrate processing chambers, such as for a physical vapor deposition (PVD) system, are provided herein.

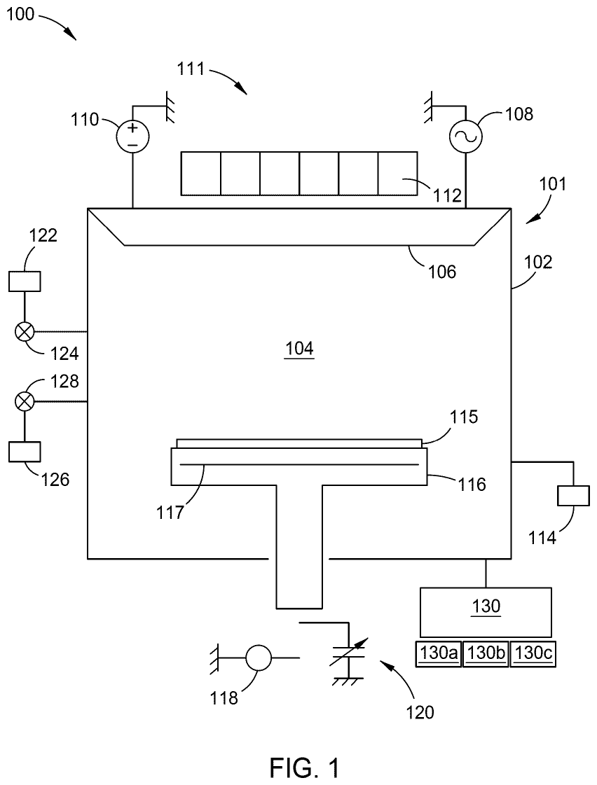

FIG. 1 illustrates a schematic view of a physical vapor deposition (PVD) processing system 100, according to some embodiments. The PVD system 100 includes a chamber 101. The PVD system 100 may be used to perform the methods described herein. The chamber 101 is a PVD chamber. It is to be understood that the chamber 101 is an exemplary PVD chamber and other PVD chambers may be used with the target assemblies described herein.

The chamber 101 includes a chamber body 102 having chamber walls that define a processing volume 104. The chamber 101 further includes a target 106 and a substrate support 116, disposed within the processing volume 104. The target 106 is described in more detail below.

The substrate support 116 is operable to secure (e.g., chuck) a substrate 115 to the substrate support 116. The substrate is disposed within the processing volume 104 during substrate processing operations. In some embodiments, the substrate support 116 includes an electrode 117 to chuck the substrate 115. In other embodiments the substrate support 116 uses vacuum to chuck the substrate 115.

The PVD system 100 further includes an RF power supply 108, a vacuum source 114, a controller 130, an auto capacitance tuner (ACT) 120, a power source 118, a reactive gas source 126, a sputter gas source 122, a DC power supply 110, and a magnetron assembly 111.

The target 106 can be coupled to the RF power supply 108 and the DC power supply 110. Power provided from RF power supply 108 and/or the DC power supply 110 to the target 106 can be used to ignite a plasma in the processing volume 104. The plasma is formed by a sputter gas. For example, the sputter gas may be argon (Ar), oxygen (O), hydrogen (H), fluorine (F), chlorine (Cl), any combination thereof. Other reactive gases are also contemplated. The plasma may be created in the processing volume 104 by a capacitive process, an inductive process, or other plasma generation methods. In some embodiments, the target 106 is coupled to the DC power supply 110.

The magnetron assembly 111 is disposed above the substrate support 116. The magnetron assembly 111 directs magnetic fields within the processing volume 104 to regions around the target 106 in the processing volume 104. These magnetic fields can help increase a density of the plasma formed in the processing volume 104 around the target 106. In one embodiment, the magnetron assembly 111 can include one or more magnets 112 (e.g., strength magnets). The one or more magnets 112 may be arranged to provide a magnetic field which extends through the target 106 and into the processing volume 104. In some embodiments, the generated magnetic fields can trap electrons along magnetic field lines to increase the plasma ion density by enabling additional electron-gas atom collisions. The magnetron assembly 111 and the magnets 112 are adjustable to adjust the magnetic field within the process volume 104.

The vacuum source 114 is fluidly coupled to the processing volume 104. The vacuum source 114 is any device or assembly which may create a vacuum. For example, the vacuum source 114 is a vacuum pump. The vacuum source 114 maintains the processing volume 104 at a specified process pressure during processing operations. The vacuum source 114 also evacuates sputter gases, reactive gases, and other gases from the processing volume 104.

The power source 118 is coupled to the electrode 117 in the substrate support 116. The electrode 117 induces an electrical bias on the substrate 115. The power source 118 may be a RF or DC power source. In some embodiments, a self-bias may form on the substrate 115 during processing. In some embodiments, the electrode 117 may be coupled to the ACT 120. The ACT 120 is operable to adjust the capacitance (and thus impedance) from the substrate support 116 to a ground.

The reactive gas source 126 is fluidly connected to the processing volume 104. A reactive gas flow controller 128, such as a mass flow controller (MFC), may be disposed between a reactive gas source 126 and the process volume 104. The reactive gas flow controller 128 controls a flow of the reactive gas (e.g., oxygen) from the reactive gas source 126 to the processing volume 104.

The sputter gas source 122 is fluidly connected to the processing volume 104. A sputter gas flow controller 124, such as a MFC, may be disposed between the sputter gas source 122 and the processing volume 104. The sputter gas flow controller 124 controls a flow of the sputter gas (e.g., argon) from the sputter gas source 122 to the processing volume 104.

The PVD system 100 further includes a controller 130. The controller 130 includes a programmable central processing unit (CPU) 130a which is operable with a memory 130b (e.g., non-volatile memory) and support circuits 130c. The support circuits are conventionally coupled to the CPU and comprise cache, clock circuits, input/output subsystems, power supplies, and the like, and combinations thereof coupled to the various components of PVD system 100, to facilitate control thereof. The CPU 130a is one of any form of general purpose computer processor used in an industrial setting, such as a programmable logic controller (PLC), for controlling various components and sub-processors of the processing system. The memory 130b, coupled to the CPU 130a, is non-transitory and is typically one or more of readily available memories such as random access memory (RAM), read only memory (ROM), floppy disk drive, hard disk, or any other form of digital storage, local or remote.

Typically, the memory 130b is in the form of a non-transitory computer-readable storage media containing instructions (e.g., non-volatile memory), which when executed by the CPU 130a, facilitates the operation of PVD system 100. The instructions in the memory 130b are in the form of a program product such as a program that implements the methods of the present disclosure. The program code may conform to any one of a number of different programming languages. In one example, the disclosure may be implemented as a program product stored on computer-readable storage media for use with a computer system. The program(s) of the program product define functions of the embodiments (including the methods described herein).

Illustrative non-transitory computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory devices, e.g., solid state drives (SSD)) on which information may be permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods set forth herein, or portions thereof, are performed by one or more application specific integrated circuits (ASICs), field-programmable gate arrays (FPGAs), or other types of hardware implementations. In some other embodiments, the substrate processing and/or handling methods set forth herein are performed by a combination of software routines, ASIC(s), FPGAs and, or, other types of hardware implementations. One or more system controllers 130 may be used with one or any combination of the various systems described herein.

As used herein, ‘a CPU,” “a processor,” “at least one processor” or “one or more processors” generally refers to a single processor configured to perform one or multiple operations or multiple processors configured to collectively perform one or more operations. In the case of multiple processors, performance the one or more operations could be divided amongst different processors, though one processor may perform multiple operations, and multiple processors could collectively perform a single operation. Similarly, “memory,” “at least one memory,” or “or more memories” generally refers to a single memory configured to store data and/or instructions, multiple memories configured to collectively store data and/or instructions.

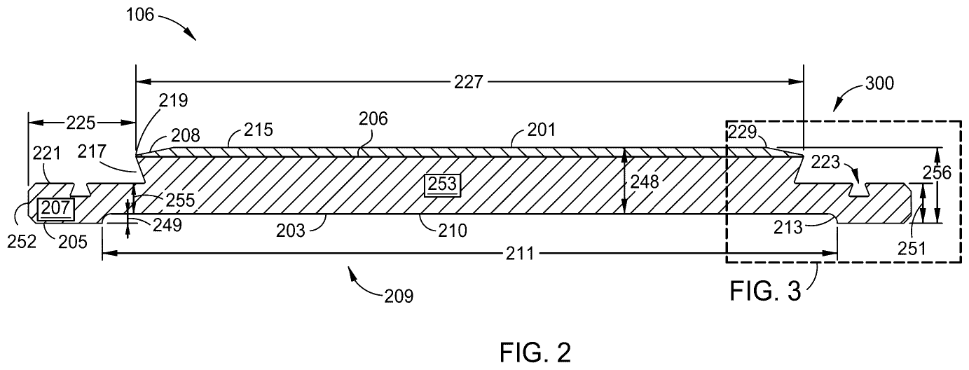

FIG. 2 is a schematic, cross-sectional view illustrating the target 106, according to embodiments described in greater detail below. The target 106 is a single metallic layer formed on a body. In some embodiments, the target 106 is a molybdenum (Mo) physical vapor deposition (PVD) target material 201, i.e., a PVD target disposed on a backer plate 203. In other embodiments, the target material 201 is molybdenum with trace amounts of other elements.

The target material 201 may also include tungsten (W), titanium (Ti), tantalum (Ta), silver (Ag), nickel (Ni), cobalt (Co), chromium (Cr), zinc (Zn), or any combination thereof.

In one example, the target material 201 may be molybdenum having a target material purity greater than 98%. For example, the target material 201 is Mo having a purity range of about 99.9% to about 99.995%. In yet another example, the target material 201 has a purity range of about 99.9% to about 99.996%. It is contemplated that having purity of 99.995% instead of 99.999% enables reduced costs to manufacture the target material 201 while still achieving increased target life, reduced applied target voltage, and reduced numbers of plasma drop out occurrences during a sputtering or deposition operation. The target material 201 has a coefficient of thermal conductivity between about 120 (Watt/m K°) to about 150 (Watt/m K°), for example about 138 (Watt/m K°). The target material 201 has a coefficient of electrical conductivity between about 40 (μ Watt cm at 20° C.) to about 60 (μ Watt cm at 20° C.), for example about 53.4 (μ Watt cm at 20° C.). The target material 201 has a plurality of grains with a major grain dimension greater than 60 micrometers. For example about 50 micrometers to about 80 micrometers. In some embodiments, the target material 201 has a grain size of 60 micrometers or greater. For example, the target material 201 has a grain size of 60 micrometers to about 70 micrometers, for example 70 micrometers to 110 micrometers. In some embodiments, the target material 201 comprises a major grain dimension less than 120 micrometers and greater than 55 micrometers.

In some embodiments, the target material 201 is a molybdenum layer with a density percentage of 99% or greater. In some embodiments, density percentage may be a volumetric density percentage of 99.99% or greater. Density percentage is the percent density of the target material 201 when compared to an idealized, nominal, or molecular density without voids or areas of porosity. For example, if a 100% molybdenum layer was compared to the target material 201, a ratio of the density of the pure Mo layer compared to the target material 201 would be 1.0 to 0.99. In some embodiments, the target material 201 has a density percentage of 99.99% or greater.

In some embodiments, the target material 201 includes anisotropic grains formed during the densification of the target material 201. In some embodiments, the anisotropic grains enable increased density percentage and a reduction in voids and porosity. The densification of the target material 201 may include a sintered molybdenum powder with a subsequent compaction operation. For example, the target material 201 may be a layer formed by sintering molybdenum powder and performing a heated compaction operation. The heated compaction may include a heated pressing or heated rolling operation performed on the sintered molybdenum powder.

In some embodiments, the target material 201 has a conductivity of about 30% to 33% of the International Annealed Copper Standard (IACS). The IACS is a measurement of how well copper conducts electricity and the percentage of conductivity provides a reference point for copper resistivity when compared to other conductors. For example, pure annealed copper has a 100% conductivity under the IACS. As described herein, the target material 201 has a conductivity of about 31% to 33%.

The backer plate 203 may be a combination of copper nickel silicon and chromium. For example, the backer plate 203 may be naval brass. In some embodiments, the backer plate 203 is brass. In some embodiments, the backer plate 203 includes zinc.

The target 106 includes the target material 201 disposed on the backer plate 203. The backer plate 203 includes a connecting face 206, a mounting region 207, recess 209, a channel 223, and a support region 253.

The target material 201 is disposed on the connecting face 206 of the backer plate 203. The target material 201 includes a process face 215 that partially defines the target material 201. The process face 215 includes a flat surface about parallel to the connecting face 206. When the target 106 is disposed in a process chamber, the process face 215 faces the substrate 115 (FIG. 1). The process face 215 includes a target material diameter 227.

The process face 215 of the target material 201 has an angled face 208 at a downward slope, toward the upper face 221, from a first process face point 229 of the process face 215 to a second process face point 219. The target material diameter 227 is defined as the diameter formed by the second process face point 219. The target material diameter 227 is about 15 inches to about 18 inches, for example about 17.5 inches.

The target 106 and molybdenum target material 201 enables the target 106 to have a voltage and a consistent current. When depositing molybdenum on the substrate 115 and applying DC power during a plasma dropout occurrence, the current spikes causing the chamber to compensate for an arcing within the chamber. The target 106 as described herein enables a current supplied to the target 106 to have a deviation not greater than 5% during a deposition operation. For example, the target 106 includes a reduced potential for a plasma dropout during a deposition operation that would cause the measured current to deviate more than 5% from the prior or subsequent units of measured current per unit of time. The plasma dropout can occur due to arcing or electrical breakdown in the chamber that causes a sudden and unintended loss of the plasma discharge within the chamber. This results in an immediate cessation of sputtering and deposition. Plasma dropouts can be intermittent or sustained, and they are generally problematic because they may cause film defects, non-uniform deposition, and process instability. The target 106 can deposit molybdenum at a reduced voltage compared to other targets and also with enables a reduced potential or no plasma drop out occurrences during deposition operations and processes due in part to one or more of the features described herein.

The target material 201 is a PVD target material. The target material 201 includes a plurality of grains. Each grain of the plurality of grains has a major grain dimension greater than 50 micrometers. The plurality of grains form an amorphous poly-crystalline structure, such that the plurality of grains are amorphous.

The target material 201 includes a major grain dimension less than 50 micrometers. The target material 201 may be sintered molybdenum according to some embodiments. The target material 201 is diffusion bonded to the backer plate.

The mounting region 207 of the backer plate 203 is disposed radially outward of the support region 253. The mounting region 207 includes an upper face 221, a mounting face 205, an outer face 252, the channel 223, an extension length 225, and mounting thickness 251.

The outer face 252 is the radially outward face of the target 106 and defines a diameter of the target 106. The outer face 252 diameter is between about 15 inches to about 48 inches. For example, between about 18 inches and about 21 inches. For example, about 20 inches.

The extension length 225 is the distance between the second process face point 219 and the outer face 252. The extension length 225 is about 2 inches to about 4 inches, for example about 3 inches.

The mounting thickness 251 is the distance between the upper face 221 and mounting face 205. The mounting thickness 251 is about 0.3 inches to about 0.7 inches, for example about 0.5 inches.

The channel 223 is formed within the upper face 221 of the mounting region 207. In some embodiments, the channel 223 is disposed radially outward of the sidewall 217 of the support region 253. For example, the channel 223 is disposed between about 0.1 inches to about 2 inches radially outward from the sidewall 217 of the support region 253. In some embodiments the channel 223 includes a dovetail geometry. The dovetail geometry enables a seal, such as an O-ring, to be disposed therein. The channel 223 is described in more detail below.

The support region 253 is disposed radially inward of the mounting region 207. A target thickness 248 is defined by the distance between the process face 215 and a recess face 210, of the recesses 209. The target thickness 248 is between about 0.7 inches to about 0.2 inches, for example about 0.27 inches to about 0.39 inches. The target thickness 248 varies radially from the center to the process face 215 to the second process face point 219.

The sidewall 217 is an angled face that partially defines the support region 253. The sidewall 217 has a height from the second process face point 219 to the upper face 221 of the mounting region 207. The sidewall 217 height is between about 0.3 inches and about 0.4 inches. For example, the sidewall 217 height is between about 0.32 inches and about 0.38 inches.

The recess 209 is disposed opposite the process face 215 of the target material 201 and opposite the upper face 221 of the mounting region 207. The recess 209 is a cavity within the target 106. The recess 209 includes the recess face 210, a recess diameter 211, a recess radius 213, and a recess depth 249.

The recess depth 249 is between the recess face 210 and the mounting face 205. The recess depth 249 is between about 0.1 inches and about 0.15 inches. The recess 209 is recessed from the mounting face 205 to the recess face 210 by the recess depth 249. In some embodiments, the recess depth 249 is between about 0.1 inches and about 0.15 inches, for example, about 0.1 inches. The recess diameter 211 is between about 17 inches and about 20 inches. In some embodiments, the recess diameter 211 is between about 17.5 inches and about 19 inches, for example about 18.5 inches. In some embodiments, the recess diameter 211 is about 89% to about 90.5% of the total diameter of the target 106.

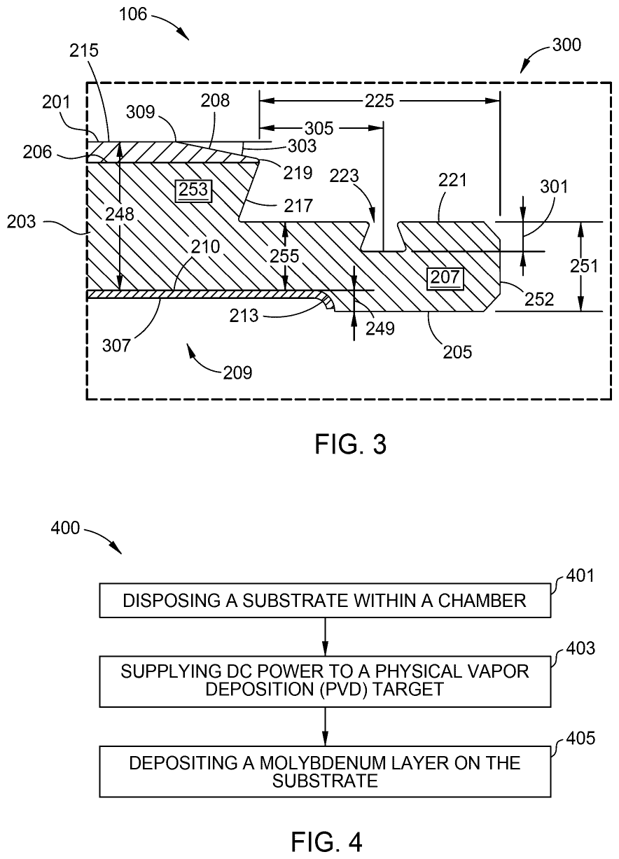

The target 106 also includes a height 256, a cross section 255, and an edge feature 300. The edge feature 300 is described in more detail in the discussion of FIG. 3. The height 256 is defined as the distance between the mounting face 205 and the process face 215. The height 256 is between about 0.85 inches and about 1.1 inches, for example, about 0.95 inches.

The cross section 255 is the thickness between the recess face 210 and upper face 221. The cross section 255 is about 0.3 inches to about 0.45 inches, for example, about 0.31 inches to about 0.35 inches. The cross section 255 is the cross sectional area of the target 106 that accounts for deflection during operation. If the cross section is too large, extra energy must be applied by the system to achieve a specific plasma density in the process volume. If the cross section 255 is too small, the target 106 experiences too much deflection that can lead to non-uniform erosion patterns and a reduction in the useful life of the target 106. In some embodiments, the cross section 255 is about 33% to about 37% of the target height 256. For example, the cross section 255 is about 35% of the target height 256.

FIG. 3 is a partial schematic, cross-sectional view illustrating the edge feature 300 of the target 106 according to some embodiments described herein. The edge feature 300 shown in FIG. 3 illustrates the radially outward region of the support region 253, sidewalls 217, and mounting region 207 according to some embodiments.

As illustrated in FIG. 3, the recess face 210 and recess radius 213 include an optional coating 307. The coating 307 is a Ni coating in some embodiments. In other embodiments, the coating 307 is a Ni—Cr coating. In other embodiments, the coating 307 is a zirconium (Zr) coating. The coating 307 has a thickness of about 0.001 inches to about 0.02 inches, for example, 0.01 inches to about 0.015 inches. The coating 307 creates a corrosion resistant film so that any coolant on the back of the target 106 does not react with the recess face 210 and radius 213 of the recess 209. In targets that have a target attached to a backer plate, the backer plate can be selected to have corrosion resistant properties. In some embodiments where the backer plate 203 is not Mo, then the coating may be omitted.

The mounting region includes the channel 223. The center of the channel 223 is disposed about 0.82 inches to about 0.84 inches from the sidewalls 217. For example, the center of the channel 223 is disposed about 0.83 inches from the sidewalls 217. The channel 223 includes a depth 301. The depth 301 is the distance that the channel 223 is recessed into the upper face 221. The depth 301 is about 0.13 inches to about 0.15 inches from the upper face 221.

As shown, in FIG. 3, the process face 215 includes the first process face point 229 and the second process face point 219. The first process face point 229 is where the angled face 208 begins to slope down toward the upper face 221. The first process face point 229 may also define an inner diameter of the process face 215. The inner diameter may be about 15 inches to about 17 inches. For example, the first process face point 229 may define an inner diameter of the process face 215 of about 16.4 inches. The downward slope of the angled face 208 is at an edge angle 303. The edge angle 303 is between about 0° and about 45° from the process surface 215. The angled face 208 intersects the sidewalls 217 at the second process face point 219. The sidewalls 217 are perpendicular to the upper face 221 of the mounting region 207.

As shown, the channel 223 is disposed radially outward of the support region 253 and recess 209. This location further aids the target 106 by allowing additional strength to be imparted to the target rigidity through the cross section 255. If the recess 209 and channel 223 were overlapped, the cross section 255 would be further reduced, limiting the strength and rigidity of the target 106, which would diminish the target 106 life.

The inventors have found the surprising effect that by increasing volumetric density of a target material 201, less voltage is required to produce a higher density plasma. The inventors have also found that the increased density reduces the occurrence of plasma dropouts and the resistance of the target material 201 during sputtering operations, allowing for enhanced throughput when using the target 106. For example, a target 106 with a molybdenum target material 201 having one or more of a purity of 99.9% or greater, a density of 99.99% or more, and/or a grain size greater than 55 micrometers, will have a longer usable life. In some embodiments, the target 106 has a resistivity of 20 ohms or less. For example, the target 106 will have a resistivity between about 15 ohms and about 18 ohms.

FIG. 4 is a flow diagram of a method of sputtering according to one or more embodiments described herein.

At operation 401, a substrate is disposed within a chamber. For example, the substrate 115 is disposed within the chamber 101.

At operation 403 the DC power supply 110 supplied DC power to the target 106. In some embodiments the target 106 is a physical vapor deposition (PVD) target. The target 106 includes the molybdenum target material 201 and the backer plate 203 (FIG. 2). As described herein, the DC power supply 110 applies direct current and voltage to the target 106. Reducing the amount of applied voltage to the target 106 enables an increased target 106 workable life. Workable life includes the functional life of target 106 to continue to deposit the molybdenum target material 201 uniformly on the substrate 115.

At operation 405, molybdenum is deposited on substrate 115. The density of target material 201 being 99% or greater enables depositing the molybdenum layer on the substrate 115 with reduced plasma drop out and at current with deviations less than 5%. As density of the molybdenum target material 201 increases, the potential for plasma dropouts at reduced voltages is reduced. For example, a molybdenum target material 201 with a volumetric density of 99.995% can have a current and voltage applied to the target 106 that enhances working target life and reduces arcing within the chamber.

In some embodiments, the method 400 is performed iteratively and the target 106 (FIG. 1) is supplied with DC power for 1800 hours or more. The density of target material 201 enables a workable life of the target 106 of 1800 hours or more.

When the word “approximately” or “about” are used, this term may mean that there may be a variance in value of up to +10%, of up to 5%, of up to 2%, of up to 1%, of up to 0.5%, of up to 0.1%, or up to 0.01%.

While the foregoing is directed to embodiments of the present disclosure, other and further embodiments of the disclosure may be devised without departing from the basic scope thereof, and the scope thereof is determined by the claims that follow.

What is claimed is:

1. A physical vapor deposition (PVD) target material for semiconductor manufacturing, the PVD target material comprising:
molybdenum; and
a density of 99.9% or greater.

2. The PVD target material of claim 1, wherein the PVD target material is molybdenum with a purity range of about 99.9% to about 99.996%.

3. The PVD target material of claim 2, wherein the PVD target material further comprises a plurality of grains comprising a major grain dimension greater than 60 micrometers.

4. The PVD target material of claim 3, wherein the PVD target material comprises a major grain dimension less than 120 micrometers.

5. The PVD target material of claim 1, wherein the density is a volumetric density of 99.99% or more.

6. The PVD target material of claim 1, wherein the target material includes anisotropic grains.

7. A physical vapor deposition (PVD) target for semiconductor manufacturing, the PVD target comprising:
a backer plate; and
a target material disposed on the backer plate, the target material comprising:
molybdenum; and
a volumetric density of 99.99% or greater.

8. The PVD target of claim 7, wherein the PVD target material has a target life of 1800 hours or more.

9. The PVD target of claim 8, wherein the PVD target material has a purity range of about 99.9% to about 99.996%.

10. The PVD target of claim 9, wherein the PVD target material has a conductivity of 31% percent or more compared to the International Annealed Copper Standard (IACS).

11. The PVD target of claim 7, wherein the PVD target material has a resistivity of less than 20 ohms.

12. The PVD target of claim 7, wherein the PVD target material includes anisotropic grains.

13. The PVD target of claim 7, wherein the backer plate includes naval brass.

14. The PVD target of claim 7, wherein the target material further comprises a plurality of grains comprising a major grain dimension greater than 60 micrometers.

15. A method of sputtering comprising:
disposing a substrate within a chamber;
supplying DC power to a physical vapor deposition (PVD) target, the target comprising:
a backer plate; and
a target material disposed on the backer plate, the target PVD material having a density of 99.9% or greater; and
depositing a molybdenum layer on the substrate.

16. The method of claim 15, wherein the target material is molybdenum.

17. The method of claim 15, wherein the target material has a conductivity of about 31% to 33% of the International Annealed Copper Standard (IACS).

18. The method of claim 15, wherein supplying DC power includes suppling a current to the PVD target wherein the current has a deviation not greater than 5%.

19. The method of claim 15, wherein the method is performed iteratively and the target is supplied with DC power for 1800 hours or more.

20. The method of claim 15, wherein the target material further comprises plurality of grains comprising a major grain dimension of about 60 micrometers to 70 micrometers.
